(19) United States
(12) Patent Application Publication
(10) Pub. No.: US 2005/0211982 A1
(43) Pub. Date: Sep. 29, 2005

(54) Strained silicon with reduced roughness

(76) Inventors: Ryan Lei, Hillsboro, OR (US); Mohamad Shaheen, Portland, OR (US); Chris Barns, Portland, OR (US); Been-Yih Jin, Lake Oswego, OR (US); Justin Brask, Portland, OR (US)

Correspondence Address: Michael A. Bernadicou;BLAKELY, SOKOLOFF, TAYLOR & ZAFMAN LLP, Seventh Floor, 12400 Wilshire Boulevard, Los Angeles, CA, 90025, US

(21) Appl. No.: 10/808,021

(22) Filed: Mar. 23, 2004

(51) Int. Cl. H01L 29/04; H01L 29/10; H01L 31/036; H01L 29/12; H01L 21/336

(52) U.S. Cl. 257/65

(57) ABSTRACT

The invention provides a strained silicon layer with a reduced roughness. Reduced cross-hatching in the strained silicon layer may allow the reduced roughness.

### BACKGROUND

### BACKGROUND OF THE INVENTION

The performance levels of various semiconductor devices, such as transistors, are at least partly dependent on the mobility of charge carriers (e.g., electrons and/or electron vacancies, which are also referred to as holes) through the semiconductor device. In a transistor, for example, the performance of the transistor is at least partly dependent on the mobility of the charge carriers through the channel region. Strained silicon can provide increased mobility of charge carriers.

When fabricating microelectronic devices, surface morphology of layers can affect the performance of the device. Conventional processes to produce strained silicon layers result in layers with a pronounced cross-hatch pattern with trenches and ridges at the surface. This cross-hatched surface has a high roughness.

### BRIEF DESCRIPTION OF THE DRAWINGS

FIG. 1 is a flow chart that illustrates how a strained silicon layer with low roughness may be formed according to one embodiment of the present invention.

FIG. 2 is a cross sectional side view that illustrates an embodiment of a graded silicon germanium layer formed on a substrate.

FIG. 3 is a cross sectional side view that illustrates an embodiment of a relaxed silicon germanium layer formed on a graded silicon germanium layer.

FIG. 4 is a cross sectional side view that illustrates an embodiment of a relaxed silicon germanium layer after polishing.

FIG. 5 is a cross sectional side view that illustrates an embodiment of a silicon layer formed on a relaxed silicon germanium layer.

FIG. 6 is a cross sectional side view that illustrates a device that may be formed by the various methods described herein.

### DETAILED DESCRIPTION

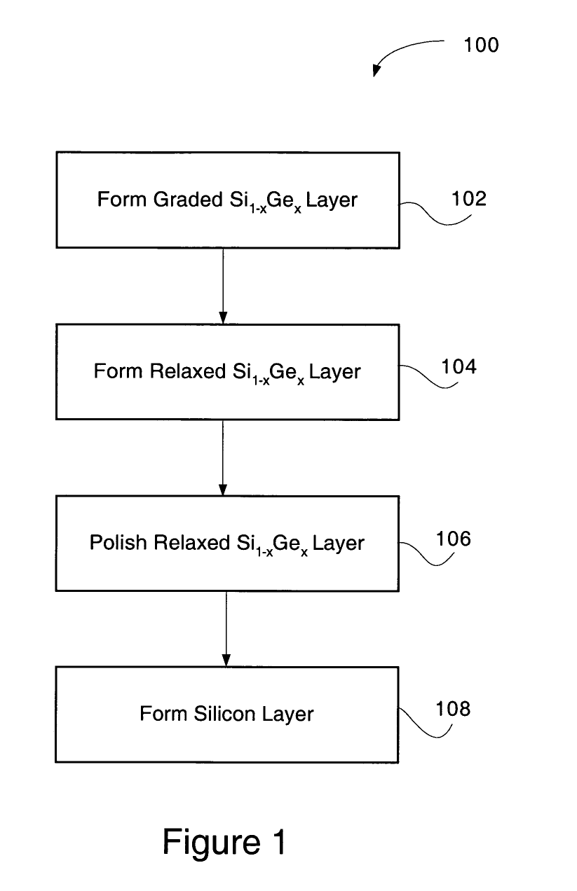

FIG. 1 is a flow chart 100 that illustrates how a strained silicon layer with low roughness may be formed according to one embodiment of the present invention. A graded silicon germanium layer may be formed 102 on a substrate in a processing chamber. In one embodiment, the substrate may be comprised of silicon, although the substrate may comprise other materials or combinations of materials in other embodiments. The processing chamber may be, among other things, a chemical vapor deposition (“CVD”) chamber, a metalorganic CVD (“MOCVD”) chamber, or a plasma-enhanced CVD (“PECVD”) chamber.

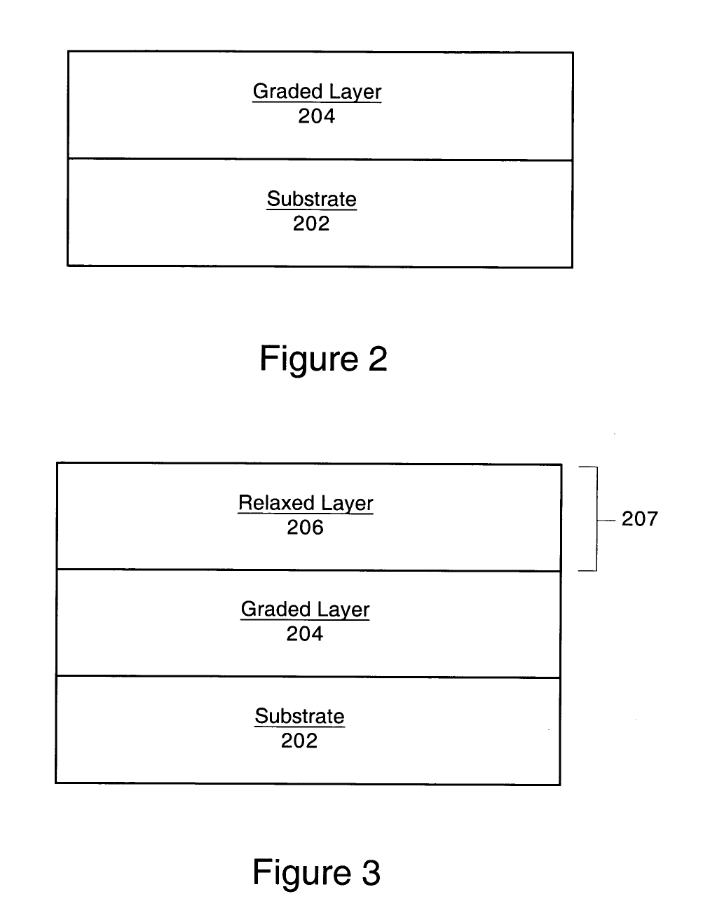

FIG. 2 is a cross sectional side view that illustrates an embodiment of a graded silicon germanium layer 204 formed 102 on a substrate 202. In one embodiment, the graded silicon germanium layer 204 may have a concentration of germanium that increases throughout the thickness of the graded silicon germanium layer 204, with less germanium at the lower end of the graded silicon germanium layer 204 (nearer to the substrate 202) and more germanium at the upper end of the graded silicon germanium layer 204 (further from the substrate 202). In various embodiments, the concentration of germanium throughout the graded silicon germanium layer 204 may be between approximately 0 percent and 30 percent. However, other concentrations beyond this range can be used.

At the upper end of the graded silicon germanium layer 204, the layer may be considered to be a layer of Si₁₋ₓGeₓ. That is, more germanium means there will be less silicon in the lattice structure of the graded silicon germanium layer 204. For a p-type metal oxide semiconductor device (“PMOS”), in one embodiment, the concentration of germanium in an upper portion of the graded silicon germanium layer 204 may be between approximately 25 percent and 30 percent (and the concentration of silicon between approximately 75 and 70 percent). For an n-type metal oxide semiconductor device (“NMOS”), in one embodiment, the concentration of germanium in an upper portion of the graded silicon germanium layer 204 may be between approximately 20 percent and 25 percent. In some embodiments, a concentration of 30 percent germanium in the upper portion of the graded silicon germanium layer 204 can work well for both PMOS and NMOS devices. Although some concentrations of germanium for PMOS devices and NMOS devices are set forth above, other concentrations may be used.

In one embodiment, the concentration of germanium in the graded silicon germanium layer may be increased by 10 percent for every micron of thickness of the graded silicon germanium layer 204. For example, a graded silicon germanium layer 204 with a thickness of 3 microns could be epitaxially grown over a period of 8-12 hours and have an increasing concentration of germanium from 0 percent at the bottom portion of the layer 204 to 30 percent at the upper portion of the layer 204. In various embodiments, the chemistry used to form the graded silicon germanium layer 204 may include one or more of silane (e.g., SiH₄), germane (e.g., GeH₄), and dichlorosilane (e.g., Cl₂Si₄), depending on the desired germanium content. The concentration of each of the particular constituents (e.g., silane, germane, dichlorosilane) may be varied during introduction into a processing chamber (e.g, a chemical vapor deposition (“CVD”) chamber) to achieve the graded effect.

Returning to FIG. 1, a relaxed silicon germanium layer may be formed 104 on the graded silicon germanium layer 204. FIG. 3 is a cross sectional side view that illustrates an embodiment of a relaxed silicon germanium layer 206 formed 104 on a graded silicon germanium layer 204. The relaxed silicon germanium layer 206 may be formed 104 in the same or a different processing chamber as the graded silicon germanium layer 204. The relaxed silicon germanium layer 206 may have a constant concentration of germanium that is approximately the same as that of an upper portion of the graded silicon germanium layer 204. Thus, the relaxed silicon germanium layer 206 may be represented by Si₁₋ₓGeₓ and have the same value of “x” as the Si₁₋ₓGeₓ at the top of the graded silicon germanium layer 204 in some embodiments. The relaxed silicon germanium layer 206 may be formed 104 to a first thickness 207. In one embodiment, this thickness 207 may be in a range between approximately 0.05 and 1 micron. In one embodiment, the thickness 207 may be in a range between about 1000 and 3000 angstroms. In one embodiment, this thickness 207 may be about 2000 angstroms.

Like the graded silicon germanium layer 204, the relaxed silicon germanium layer 206 may be epitaxially grown in some embodiments. In various embodiments, the chemistry used to form the graded silicon germanium layer 204 may include one or more of silane (e.g., SiH₄), germane (e.g., GeH₄), and dichlorosilane (e.g., Cl₂Si₄), depending on the desired germanium content. The concentration of each of the particular constituents (e.g., silane, germane, dichlorosilane) may be determined by the amount of germanium desired in the relaxed silicon germanium layer 206.

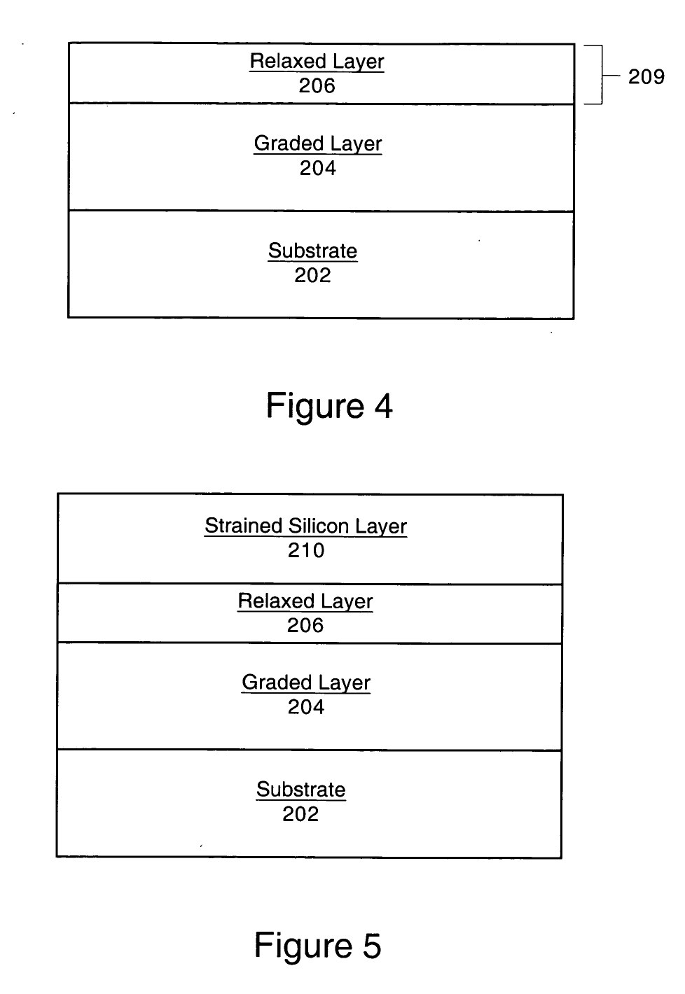

Returning to FIG. 1, the relaxed silicon germanium layer 206 may be polished 106. FIG. 4 is a cross sectional side view that illustrates an embodiment of a relaxed silicon germanium layer 206 after polishing 106. In some embodiments, the polishing 106 may be done by a chemical mechanical polish (“CMP”) process, although other methods may be used. For example, in one embodiment the relaxed silicon germanium layer 206 may be polished 106 by a CMP process for about sixty seconds. In another embodiment, the relaxed silicon germanium layer 206 may be polished 106 by a CMP process for about three minutes. In yet other embodiments, the relaxed silicon germanium layer 206 may be polished 106 by a CMP process for a time in a range of about 45 seconds to about four minutes.

The polish 106 process may remove surface roughness and/or cross hatching at the top surface of the relaxed silicon germanium layer 206 and reduce the first thickness 207 of the relaxed silicon germanium layer 206 to a smaller thickness 209. For example, in one embodiment the relaxed silicon germanium layer 206 may have a thickness 207 before polishing 106 of about 2000-5000 angstroms and a thickness 209 after polishing 106 of about 1000-2500 angstroms. CMP polish times using typical industry standard slurries are in the range of 30-180 seconds.

Returning again to FIG. 1, a silicon layer may be formed 108 on the relaxed silicon germanium layer 206. FIG. 5 is a cross sectional side view that illustrates an embodiment of a silicon layer 210 formed 108 on a relaxed silicon germanium layer 206. In some embodiments, the silicon layer 210 may be formed 108 directly on the polished surface of the relaxed silicon germanium layer 206. The chemistry used to form the silicon layer 210 may include silane. In some embodiments, the silicon layer 210 may have a thickness between approximately 50 angstroms and 1000 angstroms, although other thicknesses are also possible. In an embodiment, the silicon layer 210 may have a thickness of about 200 angstroms.

Formation of a silicon layer, such as silicon layer 210, on a silicon germanium layer, such as relaxed silicon germanium layer 206, results in a strained silicon layer due to the mismatch in lattice size between silicon and silicon germanium. The silicon germanium has a larger lattice due to the germanium content. Thus, the silicon layer expands (e.g., becomes strained) in order to match up with the silicon germanium lattice. The strained silicon may improve charge carrier mobility through the device. Thus, since the silicon layer 210 is formed 108 on a silicon germanium layer 206, the silicon layer 210 is a strained silicon layer 210.

The strained silicon layer 210 formed 108 on the polished relaxed silicon germanium layer 206 may have a relatively smooth surface, with greatly reduced or eliminated cross-hatching surface morphology. For example, a silicon layer 210 with a thickness of about 200 angstroms was formed directly on a relaxed silicon germanium layer 206 after a relaxed silicon germanium layer 206 was polished by CMP for about sixty seconds. This process was repeated and the surface roughnesses of the resulting silicon layers 210 were measured. The top surface of the silicon layer 210 (the surface furthest from the relaxed silicon germanium layer 206) had a roughness in a range from about 0.3 nanometers RMS to about 0.8 nanometers RMS. Polishing the relaxed silicon germanium layer 206 led to a reduction in cross-hatching and thus a reduction in roughness of the strained silicon layer 210.

In another example, a silicon layer 210 with a thickness of about 200 angstroms was formed directly on a relaxed silicon germanium layer 206 after a relaxed silicon germanium layer 206 was polished by CMP for about 180 seconds. This process was repeated and the surface roughnesses of the resulting silicon layers 210 were measured. The top surface of the silicon layer 210 (the surface furthest from the relaxed silicon germanium layer 206) had a roughness in a range from about 0.25 nanometers RMS to about 0.5 nanometers RMS. Both of these results contrast with roughness measurements of strained silicon layers on non-polished relaxed silicon germanium layers, which had an average surface roughness of about 2 nanometers RMS. Polishing the relaxed silicon germanium layer 206 led to a reduction in cross-hatching and thus a reduction in roughness of the strained silicon layer 210.

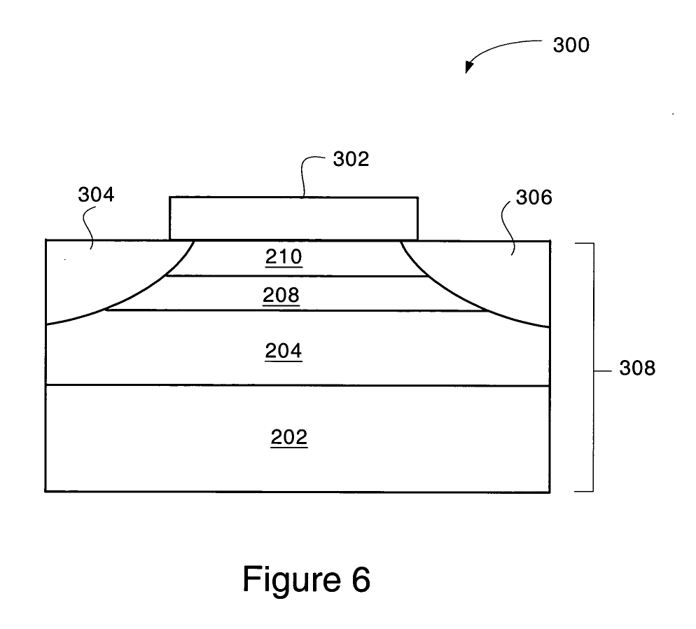

FIG. 6 is a cross sectional side view that illustrates a device 300 that may be formed by the various methods described herein. Other devices may also be formed that comprise the strained silicon layer described herein. Device 300 may include a composite substrate 308 with a first source/drain region 304 and a second source/drain region 306 formed therein. Gate electrode 302 may be formed on a surface of the composite substrate 308. Composite substrate 308 may also include, in this embodiment, a substrate 202 that comprises silicon.

A channel region of device 300 (e.g., below gate electrode 302, as shown in FIG. 6) may include a portion of a graded silicon germanium layer 204, a relaxed silicon germanium layer 206, and a strained silicon layer 210, all of which may be formed as described with respect to FIGS. 1 through 5, above. In other embodiments, the channel region may not include each of the graded silicon germanium layer 204, relaxed silicon germanium layer 206, and strained silicon layer 210. In yet other embodiments, the graded silicon germanium layer 204, relaxed silicon germanium layer 206, and strained silicon layer 210 may have a different thicknesses compared to the source/drain regions 304, 306, such that the source/drain regions 304, 306 may extend well below the bottom of the graded silicon germanium layer 204, for example.

To form the device 300, a graded silicon germanium layer 204 may be disposed on substrate 202. As described above, in one embodiment, a graded silicon germanium layer 204 has an increasing concentration of germanium throughout its thickness. For example, graded silicon germanium layer 204 in the device 300 may have a concentration of germanium that increases by 10 percent for every micron of thickness of the graded silicon germanium layer 204.

A relaxed silicon germanium layer 206 may be disposed on the graded silicon germanium layer 204 in the device 300 and then polished by CMP or other methods. The relaxed silicon germanium layer 206 may have a constant concentration of germanium throughout its thickness. In one embodiment, relaxed silicon germanium layer 206 may have approximately the same concentration of germanium as the concentration of germanium in an upper portion of the graded silicon germanium layer 204. In some embodiments, the relaxed silicon germanium layer 206 may have a thickness of between approximately 0.5 and 1.0 micron after CMP or other polishing.

A strained silicon layer 210 may be disposed on the polished relaxed silicon germanium layer 206 in the device 300. In some embodiments, the silicon layer 210 may have a thickness between approximately 50 Å and 1000 Å. Due to the difference in lattice size of relaxed silicon germanium layer 206 and silicon layer 210, silicon layer 210 is strained, which enhances charge carrier mobility through the channel region of device 300. Device 300, with its enhanced charge carrier mobility, can be advantageously used, for example, as a transistor in any suitable circuit.

The foregoing description of the embodiments of the invention has been presented for the purposes of illustration and description. It is not intended to be exhaustive or to limit the invention to the precise forms disclosed. Some layers and steps may be added and other layers or steps added. This description and the claims following include terms, such as left, right, top, bottom, over, under, upper, lower, first, second, etc. that are used for descriptive purposes only and are not to be construed as limiting. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. A method, comprising:
depositing a graded silicon germanium layer on a substrate;
depositing a relaxed silicon germanium layer on the graded silicon germanium layer;
polishing the relaxed silicon germanium layer; and
depositing a strained silicon layer directly on the polished relaxed silicon germanium layer.

2. The method of claim 1, wherein the strained silicon layer has a first surface adjacent the polished relaxed silicon germanium layer and a second surface substantially opposite the first surface and the second surface has a roughness of about 1.0 nanometers RMS or less.

3. The method of claim 1, wherein the strained silicon layer has a first surface adjacent the polished relaxed silicon germanium layer and a second surface substantially opposite the first surface and the second surface has a roughness of about 0.5 nanometers RMS or less.

4. The method of claim 1, wherein the strained silicon layer has a thickness in a range from about 150 angstroms to about 1000 angstroms, and polishing the relaxed silicon germanium layer comprises chemical mechanically polishing the relaxed silicon germanium layer for at least approximately 60 seconds.

5. The method of claim 1, wherein depositing a relaxed silicon germanium layer comprises depositing a relaxed silicon germanium layer with a thickness in a range between about 2000 angstroms and about 5000 angstroms and polishing the relaxed silicon germanium layer comprises removing about half the thickness of the deposited relaxed silicon germanium layer.

6. The method of claim Al, wherein polishing the relaxed silicon germanium layer comprises chemical mechanically polishing the relaxed silicon germanium layer for at least approximately 60 seconds.

7. A device, comprising:
a substrate; and
a strained silicon layer on the substrate, wherein the strained silicon layer has a surface roughness of about 1.0 nanometers RMS or less.

8. The device of claim 7, further comprising a relaxed silicon germanium layer between the substrate and the strained silicon layer.

9. The device of claim 8, further comprising a graded silicon germanium layer between the substrate and the relaxed silicon germanium layer.

10. The device of claim 8, wherein the strained silicon layer is directly on the relaxed silicon germanium layer.

11. The device of claim 8, wherein relaxed silicon germanium layer has a polished surface and wherein the strained silicon layer is directly on the polished surface of the relaxed silicon germanium layer.

12. The device of claim 7, wherein the strained silicon layer has a surface roughness of about 0.5 nanometers RMS or less.

13. A device, comprising:
a substrate;
a graded silicon germanium layer on the substrate;
a relaxed silicon germanium layer on the graded silicon germanium layer, the relaxed graded silicon germanium layer having a first surface closer to the graded silicon germanium layer and a polished second surface further from the graded silicon germanium layer; and
a strained silicon layer directly on the polished second surface of the relaxed silicon germanium layer.

14. The device of claim 13, wherein the strained silicon layer has a surface roughness of about 1.0 nanometers RMS or less.

15. The device of claim 13, further comprising:
a first source/drain region adjacent the strained silicon layer;
a second source/drain region adjacent the strained silicon layer and spaced apart from the first source/drain region by the strained silicon layer; and
a gate electrode on the strained silicon layer.
